(19) United States
(12) Patent Application Publication
(10) Pub. No.: US 2003/0198749 A1
(43) Pub. Date: Oct. 23, 2003

(54) Coated silicon carbide cermet used in a plasma reactor

(75) Inventors: Ananda H. Kumar, Fremont, CA (US); Robert W. Wu, Pleasanton, CA (US); Gerald Zheyao Yin, San Jose, CA (US); Gabriel Bilek, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/125,135

(22) Filed: Apr. 17, 2002

(51) Int. Cl. C23F 1/00; C23C 16/00; H01L 21/306; B05D 3/02

(52) U.S. Cl. 427/376.3; 156/345.1; 118/723 R

(57) ABSTRACT

A complexly shaped Si/SiC cermet part including a protective coating deposited on a surface of the cermet part facing the plasma of the reactor. The cermet part is formed by casting a SiC green form and machining the shape into the green form. The green form is incompletely sintered such that it is unconsolidated and shrinks by less than 1% during sintering. Molten silicon is flowed into the voids of the unconsolidated sintered body. Chemical vapor deposition or plasma spraying coats onto the cermet structure a protective film of silicon carbide, boron carbide, diamond, or related carbon-based materials. The part may be configured for use in a plasma reactor, such as a chamber body, showerhead, focus ring, or chamber liner.

### FIELD OF THE INVENTION

The invention relates generally to plasma processing equipment. In particular, the invention relates to silicon carbide parts, particularly those that are complexly and used in a plasma processing reactor.

### BACKGROUND ART

Many of the steps in modem manufacturing of semiconductor integrated circuits rely upon plasma processing. Of the several types of processes, plasma etching presents some of the most challenging requirement for reactor parts exposed to the plasma since the reactor part may be etched with chemistry closely related to the desired etching of the substrate. Most etch chemistries rely upon halogen plasmas, where the halogen may be fluorine, chlorine, or bromine. Almost all dielectric etching, for example, of silicon dioxide and the related silicate glasses, uses a fluorine plasma in which the fluorine radical reacts with the silicon to form volatile SiF₄. Most metal etching uses chlorine plasma. Silicon etching often uses a bromine plasma. Iodine has not found much favor in silicon processing.

A plasma reactor requires a vacuum chamber to confine the plasma, and other parts may be placed in the chamber in contact with the plasma. Particularly vacuum chambers are most conveniently formed of forged aluminum because of its economy, ease of manufacture, vacuum tightness, and its relatively high electrical conductivity. The last feature is needed when the chamber wall is acting as one of the plasma electrodes.

However, aluminum readily reacts with halogen plasmas, and the reaction products may includes small particles of aluminum fluoride or aluminum chloride which may fall on the wafer and cause a major particulate problem.

For these reasons, it has become standard practice to coat aluminum chamber walls and other chamber parts with a protective coating. Anodization of aluminum has been most prevalently practiced, and the technology has developed to improve the resistance of the anodization to plasma attack. However, anodized aluminum invariably develops flaws.

Anodized aluminum grows as vertical crystallites of aluminum oxide on the aluminum substrate, and a relatively small amount of etching of the aluminum oxide may free a relatively large crystallite. Furthermore, the coefficient of thermal expansion (CTE) of aluminum has a value of about 26×10⁻⁶/° C., which differs significantly from that of aluminum oxide, which is about 8×10⁻⁶/° C. As a result, as the reactor is repetitively cycled in temperature, the anodization layer is likely to flake off the aluminum substrate, both causing a particle problem and exposing the underlying aluminum to the halogen plasma.

A further problem arises with protective anodization layers. In most etching chemistries polymers or other reaction byproducts build up on chamber walls and other parts. If the buildup becomes extensive, it affects the chemistry. A substantial buildup is highly likely to produce particles as portions of the buildup flakes off. The chamber wall can be periodically cleaned, but cleaning interrupts production and requires operator time. One preferred method of avoiding particle buildup is to periodically to form an oxygen plasma in the chamber with the electrical bias reversed so that the oxygen plasma etches the chamber walls and dissolves the polymer or other residue. However, an oxygen plasma would also quickly etch the anodization, thus reducing its lifetime. Oxygen plasmas are also used for substrate cleaning, such as photoresist stripping.

Other types of protective coatings have been applied to aluminum chambers. Shih et al. in U.S. Pat. No. 6,120,640, incorporated herein by reference in its entirety, have disclosed one of the most successful ones, boron carbide having a composition near to B₄C. Boron carbide is an extremely rugged refractory material and is not significantly attached by halogen plasmas. Its coefficient of thermal expansion of 5.54×10⁻⁶/° C. differs somewhat more from that of aluminum than does α alumina, but the increased fracture strength of boron carbide relative to that of an anodized layer results in less peeling. However, while boron carbide coatings on aluminum have been demonstrated to be vastly superior to anodized aluminum, the coating still develops cracks over extended usage so chamber lifetimes are still limited. As integrated circuit manufacturing technology pushes to feature sizes of 0.13 μm and less, even boron carbide coatings become problematical.

Another approach relies upon silicon carbide (SiC), another refractory material that does not react with halogen plasmas. Silicon carbide is widely available at moderate cost, and it can be formed with an adequate electrical conductivity for plasma chambers. Most large silicon carbide members are formed by sintering, in which small particles of silicon carbide are fused together. However, the fusion is not complete and foreign matter introduced in the sintering process is typically left between the silicon carbide particles, introducing a contamination issue. Furthermore, etching of the foreign matter may release microscopic particles of silicon carbide, introducing a particle issue. As a result, sintered silicon carbide by itself is considered a dirty material for advanced plasma processing. To avoid these problems, Lu et al. have described in U.S. Pat. No. 5,904,778, incorporated herein by reference in its entirety, a silicon carbide composite in which a sintered SiC base member, for example, a vacuum chamber wall, is coated with a uniform layer of silicon carbide deposited by chemical vapor deposition (CVD). The CVD silicon carbide is clean and has virtually the same coefficient of thermal expansion as the sintered SiC so flaking is not a problem.

However, sintered silicon carbide, whether by itself or coated with CVD silicon carbide, presents substantial fabrication problems for the complex parts required of plasma reactors. Silicon carbide is one of the hardest commonly found materials and is thus difficult to machine. Indeed, most cutting tools have silicon carbide tips. It is possible to machine silicon carbide with advanced cutting tools, but it is a difficult and expensive process. The problem of machining silicon carbide can be addressed by sintering the silicon carbide in nearly its final shape. The sintering process typically involves combining the silicon carbide (or other refractory) powder with binding agents and plasticizers to form a slurry. The slurry is cast into the near final shape, and a gentle heating produces a green form that is free standing but soft. If necessary, the green form may be machined. The green form is then heated to the sintering temperature, which for silicon carbide is close to 2000° C. When the green form is held at this temperature for sufficient time, the binder and other sintering aides for the most part evaporate, and the refractory powder particles consolidate into tight material to form the sintered product. The process described to this point in the absence of pressure is called free sintering.

The conventional free sintering process, however, introduces a shrinkage of about 15%, which is often quantized as densification occurring during sintering. That is, the sintered product is about 15% smaller in all three dimensions than the green form from which it was produced. The densification occurs as the disjoint powder particles partially fuse and with continued heat treatment condense into a more compact structure. For most industrial applications, high densification is desired. For relatively simple shapes like plates and tubes, the shrinkage can be accommodated by increasing the dimensions of the green form. Alternatively, hot pressing can be used to create relatively complex forms in two dimensions. In hot pressing, the high temperature sintering is performed while the green form is being compressed in one dimension. The pressing collects all the shrinkage in the pressure direction, leaving the original, unshrunk shape in the other two dimensions.

Unfortunately, many plasma chamber parts have relatively complex shape. A chamber body 10 illustrated in the orthographic view of FIG. 2 is incorporated into the DPS etch reactor available from Applied Materials, Inc. of Santa Clara, Calif. It includes a processing cavity 12 having a generally cylindrical sidewall 14 for accommodating the pedestal supporting a wafer to be processed, a pump cavity 16 connected to a vacuum pumping system, and a port 18 connecting the two cavities 12, 16. The cavities 12, 16 and port 18 are enclosed apertures extending about respective axes arranged in two perpendicular directions. Gas jet ports 20 are formed in the processing cavity sidewall 14. An O-ring groove 22 may be formed in and around the circular top of the sidewall 14 to accommodate an elastomeric O-ring to form a vacuum seal with an unillustrated roof. Lu et al. in the above cited patent machine the illustrated shape from aluminum and then plasma spray a layer of boron carbide on the inside of the sidewall 14.

The complexly shaped chamber body 10 would be very difficult to form from sintered silicon carbide. In free sintering, if the green body were formed with the illustrated shape though with increased dimensions, the significant shrinkage would cause the shape to distort in ways too complex to compensate. A wide design margin in the green form introduces excessive machining of the sintered product. Further, the illustrated shape is completely three-dimensional and thus inappropriate for hot pressing. Performing the necessary machining upon the sintered silicon carbide product is too expensive to be practical.

Thus, conventional sintered silicon carbide, even when coated with CVD silicon carbide, is not appropriate for chamber walls and other complex parts facing the plasma. Proposals have been made to form free standing bodies of CVD silicon carbide. Such CVD bodies avoid the problems mentioned above, but it is extremely costly to make large bodies of CVD silicon carbide.

### SUMMARY OF THE INVENTION

A Si/SiC cermet is formed by flowing molten silicon into an incompletely consolidated body of sintered silicon carbide to form an infiltrate phase in the pores around the sintered silicon carbide. A protective coating is applied over the Si/SiC cermet. The protective coating may be silicon carbide deposited by chemical vapor deposition. It may alternatively be boron carbide, for example, B₄C deposited by thermal spraying, or a carbon-based film, for example, diamond, diamond-like materials, or amorphous carbon. The composition of the infiltrate phase may be changed toward SiC by precoating the pores with excess carbon.

The formed body may have a complex form, for example, including at least two enclosed apertures arranged around perpendicular axes. The complex form may be attained by casting the silicon carbide slurry into a green form, machining the green form, and then only partially sintering the machined green form such that the powder is only partially incompletely consolidated and shrinkage during sintering is less than 1%.

The coated Si/SiC cermet is particularly useful as a part exposed to a plasma environment, most particularly a halogen plasma used in etching.

### BRIEF DESCRIPTION OF THE DRAWINGS

FIG. 1 is an orthographic view of a chamber body found in the prior art.

FIG. 2 is a flow diagram of a process of forming a part for use in a plasma processing reactor.

FIG. 3 is a schematic cross-sectional view of a plasma etch reactor.

FIG. 4 is a perspective view of a chamber liner used in the reactor of FIG. 3.

### DESCRIPTION OF THE PREFERRED EMBODIMENTS

Depositing a protective coating over a base material can be approached from the alternative directions of selecting a suitable protective coating for a preferred base or selecting a suitable base for a preferred coating. Although aluminum is a preferred base, compatible protective coatings have not been found that are completely adequate for some environments. It is known that protective layers of silicon carbide, boron carbide, and diamond and its analogs provide superior protection against a halogen plasma. These materials are among the few readily available materials generally considered to exhibit covalent bonding. What is required is a base material compatible with these protective layers that can be easily formed into complex shapes.

One embodiment of the invention includes a base of a ceramic metallic (cermet) of silicon and silicon carbide (Si/SiC) in which SiC is partially sintered and thus formed with pores. It is understood that silicon carbide need not be precisely stoichiometric. The SiC matrix can be formed by only partially sintering the silicon carbide powder such that densification and consolidation is incomplete and large pores remain within the partially sintered body. Thereafter, molten silicon is flowed into those pores. The cermet structure is then coated with a compatible and continuous film of, for example, SiC, B₄C, diamond, or related carbon-based materials.

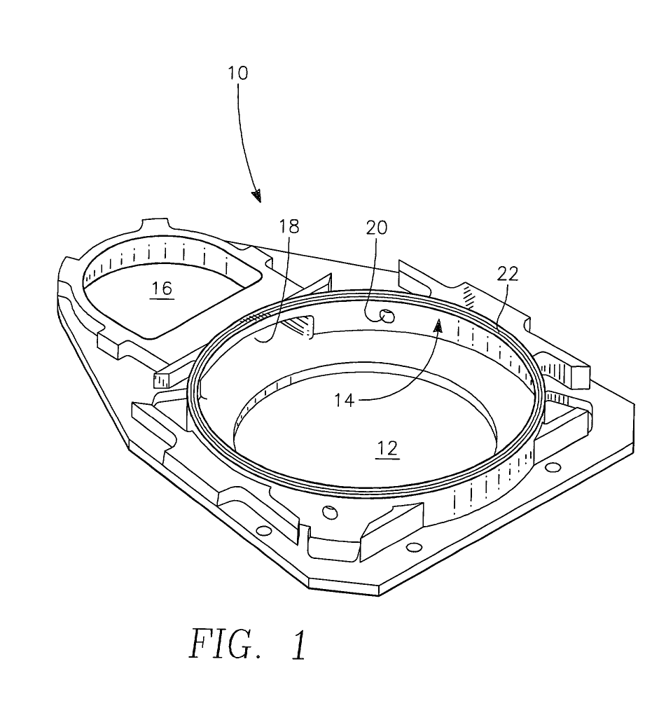

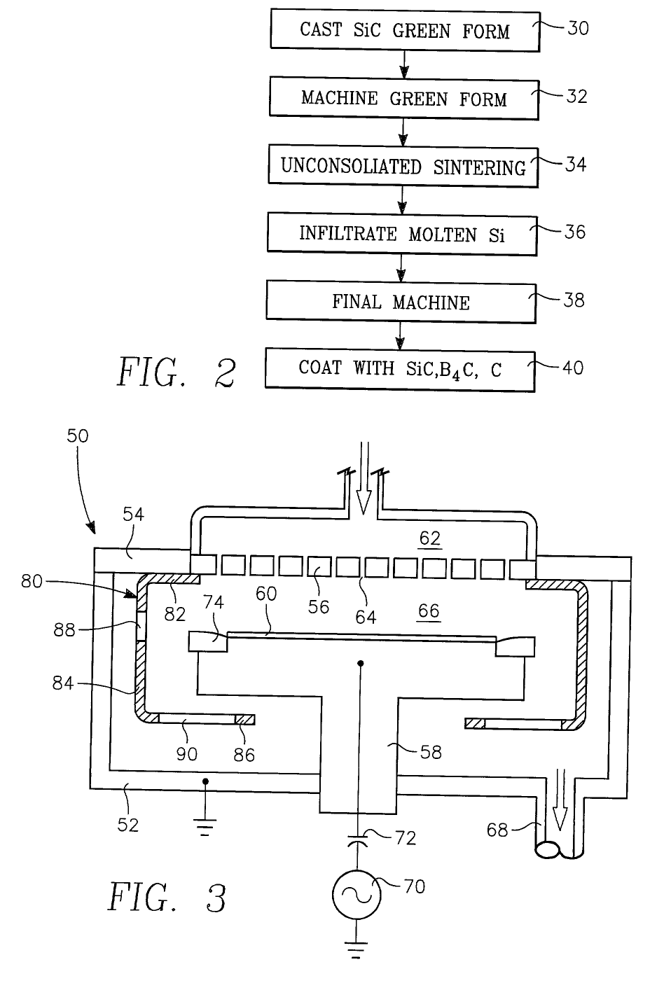

The fabrication process is described in more detail with reference to the flow diagram of FIG. 2. In step 30, a green form, also called the preform, is formed by aqueous casting into a relatively complex mold. In step 30, the preform may be easily machined with the fine details of the structure required of the chamber body of FIG. 1. That is, the green form is formed in near net shape of the final part though perhaps a fraction of a percent larger. The machining is especially important when the desired shape has apertures through it extending in perpendicular directions since casting such a structure requires destroying the mold to extract the casting.

In step 34, the green form is fired, typically in an inert atmosphere, at a temperature of about 2000° or slightly above. Free sintering is preferred although pressure sintering may be used. The firing however is not complete relative to normal silicon carbide sintering and only partially consolidates the SiC particles. The incomplete firing may be accomplished either by reducing the temperature or the duration of the firing process from the values used in a nearly completely densified sintering.

German discusses the dynamics of sintering in “Fundamentals of Sintering,” ASM Handbook, vol. 4, Ceramics and Glasses, 1991, pp. 260-284. Tanaka provides a similar discussion in “Sintering of silicon carbide,” Silicon Carbide Ceramics—1. Fundamental and Solid Reaction, eds. Somiya et al., Chap. 10, (Elsevier, 1991), pp. 213-238. It is preferred that the silicon carbide powder have a bimodal size distribution. Particles with diameters in the range of 5 to 15 μm provide strength and rigidity to the otherwise soft green form. Particles with diameters in the range of 50 to 150 μm provide large pore between the sintered particles allowing the infiltration of the molten silicon. Pore spacings in the neighborhood of 100 to 200 μm have been found in such sintered silicon carbide. However, the pore spacing additionally depends on sintering conditions and the degree of consolidation. The largely organic binder and sintering aids are volatized during the partial sintering but may leave carbon residues, which tend to dissolve in the molten silicon to form yet more silicon carbide. Linear shrinkage of the incompletely densified sintered body has been demonstrated at 0.5% from the cast preform and 0.1% from a preform that has been machined. As a result, there is relatively little distortion in the incomplete firing. Linear shrinkage of less than 1% in all three dimensions provides many of the advantages of the invention.

In step 36, silicon is flowed into the unconsolidated SiC body by placing strips of silicon adjacent the SiC body in a boat of, for example, completely densified silicon carbide or graphite, and raising the temperature in a vacuum or inert atmosphere to above 1416° C., the melting point of silicon. This temperature compares to the approximate 2000° C. used for sintering silicon carbide. Silicon wets well with silicon carbide so that it flows over the carbide surfaces of the unconsolidated sintered silicon carbide and penetrates into the pores so as to infiltrate the SiC body and bond to the sintered SiC. As stated before, carbon residue left within the pores is dissolved in the molten silicon. It may be desired to increase the carbon content of the infiltrate phase, even up to nearly stoichiometric SiC. The additional carbon may be precoated within the pores by infiltrating a resin and pyrolyzing it, as Sangeeta et al. describe in U.S. Pat. No. 5,628,938. The silicon forming the melt may be doped to affect the conductivity of the infiltrated silicon or silicon carbon infiltrate phase. In particular, the conductivity of an infiltrate composed of wide-bandgap silicon carbide may be substantially increased.

Upon cooling, the Si/SiC cermet structure has dimensions very close to the end product. The metallic silicon content may be in the range of 20 to 40 wt % and the SiC content in the range of 60 to 80% wt %. Sangeeta et al. in the aforecited patent describe the sintering of SiC and infiltration of molten silicon. However, their sintering process produces a shrinkage of 14 to 17%. Furthermore, they also coated the preform with carbon so that the silicon infiltration produces additional SiC, though in a more homogeneous metal-like phase.

Whatever fine machining is required should be performed in step 38 on the cermet structure, for example, the circular O-ring groove 22 of FIG. 1 and any threading. Although Si/SiC cermet is difficult to machine, the extent of machining at this stage may be limited.

The Si/SiC cermet structure is superior to a sintered SiC structure. The metallic-like Si or SiC infiltrate phase improves the vacuum tightness and reduces etching along the sintering grain boundaries. However, the cermet structure may still be improved use inside a plasma reactor, particularly one using halogen chemistry. To provide a pure and uniform surface, in step 40 a protective surface coating is applied on at least the side of the structure facing the plasma. A first example of a surface coating is a SiC coating applied by chemical vapor deposition (CVD), a process well known in the art to produce a highly uniform and protective coating. Hirai et al. describe the CVD formation of SiC in “Silicon Carbide Prepared by Chemical Vapor Deposition,” Silicon Carbide Ceramics—1: Fundamental and Solid Reaction, ibid., Chap. 4, pp. 77-118. The required thickness of the CVD SiC layer should be determined by the erosion rate of this material at different portions of the etch reactor dependent upon the etch processing conditions. Because of the relatively close coefficients of thermal expansion of sintered and CVD SiC (approximately 4.78 and 4.02 respectively in units of 10⁻⁶/° C.) and the extra flexibility of cermet matrix, peeling of the CVD film is much less of a problem. (It is noted that the thermal expansion coefficient for silicon is 2.6×10⁻⁶/° C.) As a result, relatively thick CVD layers of 1 and 2 mm may be deposited. For these very thick coatings, the final machining may be delayed till after the surface coating. Although it is necessary to coat only the side of chamber walls, the CVD process more naturally coats all exposed surfaces.

Boron carbide may also be used as a protective layer. Its stoichiometric form is B₄C, but it may vary somewhat from this composition, as is explained by Shih et al. Its coefficient of thermal expansion of 5.54×10⁻⁶/° C. is relatively close to the coefficient of 4.78×10⁻⁶/° C. for sintered SiC. It is known how to deposit boron carbide by CVD. However, Shih et al. have demonstrated in the above cited patent the effectiveness of thermal sprayed B₄C, in particular the use of plasma spraying. Thermal spraying has the added advantage that its application may be localized to portions of the chamber exposed to the plasma and the coating thickness may be varied between different locations according to the severity of the erosion to be experienced at those locations. For example, the area 5 around the gas jets 20 of FIG. 1 are known to suffer the worst erosion.

Another available protective coating is diamond, which has a coefficient of thermal expansion of about 4.5×10⁻⁶/° C., very close to that of SiC. Ravi in U.S. Pat. No. 5,952,060 has disclosed the use of diamond as a protective coating in plasma reactors. Ravi discloses how such carbon films are formed by CVD. Han et al. in U.S. patent application Ser. No. 09/375,243, filed Aug. 16, 1999, incorporated herein by reference in its entirety, describe diamond coating on a Si/SiC composite. A corresponding PCT publication is WO 01/13404 A1, dated Feb. 22, 2001. The film need not form in the diamond crystal structure but may be an essentially carbon film of various forms including amorphous, that is, a carbon-based film with less than 10 at % of other components than elemental carbon. Dopants may be added to increase the electrical conductivity.

Diffusion furnace tubes and wafer boats are commercially available which are formed of a Si/SiC cermet covered with a coating of CVD SiC. However, these parts are used in the much more benign environment of thermal processing rather than the harsh environment of halogen plasma etch chemistry. Furthermore, both diffusion tubes and wafer boats have a much simpler, non-critical structure than a plasma reaction vacuum chamber such that complex machining is not required and it is possible to cast in net shape and to compensate for shrinkage.

An plasma etch reactor 50 illustrated in the schematic cross-sectional view of FIG. 3 includes parts that may benefit from the invention. The etch reactor 50 includes a vacuum chamber body 52 and a roof 54. A gas distribution plate 56, alternately called a showerhead, is disposed in the roof 54 in opposition to a pedestal 58 supporting a wafer 60 to be etched. The gas distribution plate 56 includes a plurality of apertures 64 distributed over the area facing the wafer 60 across a processing space 66. The height of the processing space 66 may be relatively small, on the order of 2 to 5 cm. An etching gas, typical including a halogen-based gas, is admitted to a manifold 62 formed at the back of the gas distribution plate 56 to equalize the gas pressure before the etching gas flows through the apertures 64 into the processing space 66. An unillustrated vacuum pump connected to a pump port 68 at the bottom of the chamber keeps the chamber pressure in the milliTorr range.

The chamber body 52, the roof 54, and the gas distribution plate 56 are electrically grounded. An RF power supply 70 is connected to the pedestal 58 through a capacitive coupling capacitive circuit 72. The RF power excites the etching gas into a plasma, and a negative DC self bias that develops on the pedestal 58 attracts the positive charged etchant ion to the wafer 60 to effect the plasma etching. In a magnetically enhanced reactive ion etcher, magnetic coils or other magnetic means are positioned around the chamber sidewalls to provide a rotating horizontal magnetic field in the processing space to increase the density of the plasma. The pedestal also includes an unillustrated electrostatic chuck to hold the wafer 60 during etching and to promote thermal control by a thermal transfer gas and a cooling liquid included in the pedestal 58.

An electrically conductive plasma focus ring 74 is advantageous disposed in a peripheral recess on top of the pedestal 58 at and slightly below the top surface of the wafer 60. Electrons from the plasma condense on the focus ring 74 to negatively charge it to thereby focus the plasma toward the wafer 60. The focus ring 74 also protects the pedestal 72 and electrostatic chuck from the etching plasma. The focus ring 74 may be formed of the Si/SiC cermet material coated with a protective layer of SiC, B₄C, or diamond and its analogs with additional doping as required to make it sufficiently conductive.

The gas distribution plate 56 is also subject to a very corrosive environment as the halogen gas flows through its apertures 64 and is excited into a plasma. The gas distribution plate 56 may also be formed of the Si/SiC cermet material with a protective layer of SiC, B₄C, or diamond types of materials.

The chamber body 52 and roof 54 may also be formed of such a coated Si/SiC cermet material. The chamber body may be complexly shaped like the chamber body 10 of FIG. 1. However, it is preferred to instead rely upon a chamber liner 80 illustrated in FIG. 3 that has an inwardly extending top portion 82 connected to and protecting the roof 54, an outer portion 84 to protect the chamber sidewall, and an inwardly extending bottom portion 86 that wraps around the side and bottom periphery of the top of the pedestal 58. The chamber liner 80 is electrically grounded so that it shields the bottom of the chamber from from the plasma. If there is any excessive buildup of residue or excessive etching, the chamber liner 80 can be replaced without the need to clean or refurbish the chamber body 52.

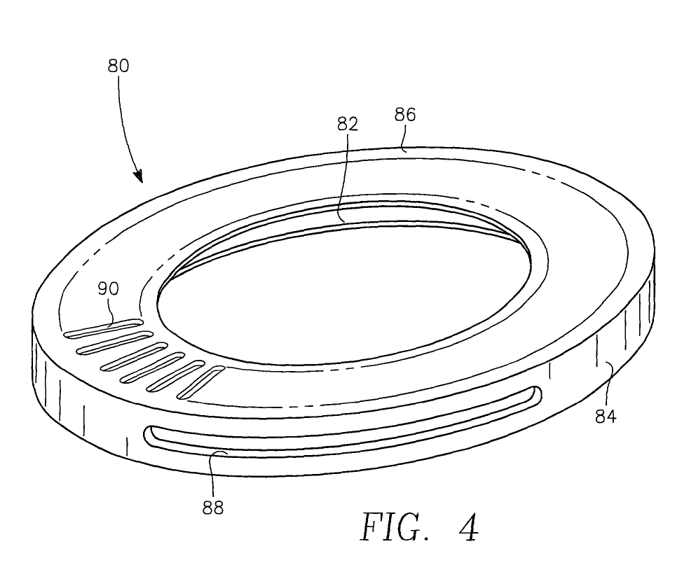

The placement of the chamber liner 80 around the processing space 66 and between the gas distribution plate 56 and the pumping port 68 requires further complexities in its design. As illustrated in the perspective view of FIG. 4, generally from the bottom of the chamber liner 80, a wide circumferential slot 88 is formed in the outer portion 84 of the liner 80 to allow the wafer 60 to be transferred to and from the pedestal 58. Further, a large number of radially extending slots or louvers 90 are formed in the bottom portion 86 of the liner 80 in a pattern extending around the annular bottom portion 86. The slots 90 louvered bottom portion 86 are preferably small enough to confine the plasma to above the liner 80 and to create sufficient flow impedance to reduce the required gas supply and pumping rates, that is, to increase the gas residence time in the processing space 66.

The chamber liner 80 is also advantageously formed of the coated Si/SiC cermet of the invention. Its significant electrical conductivity allows it to drain whatever plasma electrons condense on it, thereby enabling it to function as part of the anode. The machining of the complex shape is easily performed on the green form. No final machining is required after sintering.

The invention thus allows the economical fabrication of complex parts that are resistant to the harsh halogen plasma environment experienced in plasma etching. However, the invention is not so limited. Other plasma environments, such as oxygen plasmas, are quite harsh on some coatings. Complexly shaped silicon carbide parts for any environment may be advantageously formed according to the invention.

1. A complexly shaped part having a shape including two enclosed apertures arranged about perpendicular axes and comprising:
a base comprising a silicon/silicon-carbide cermet; and
a protective coating deposited over said base.

2. The part of claim 1, wherein said cermet comprises a partially sintered silicon carbide matrix having voids and silicon filled into said voids.

3. The part of claim 1, wherein said protective coating comprises a material selected from the group consisting of silicon carbide, boron carbide, and carbon-based materials including diamond, diamond-like materials, and amorphous carbon.

4. The part of claim 3, wherein said material is CVD silicon carbide.

5. The part of claim 3, wherein said material is thermally sprayed boron carbide.

6. The part of claim 3, wherein said material is a CVD carbon-based material.

7. The part of claim 3 which is configured to be used in a plasma substrate processing reactor with said protective coating facing a plasma therein.

8. The part of claim 1, wherein said base comprises carbon and silicon included within an infiltrate phase of said silicon/silicon-carbide cermet.

9. A method of forming a protected cermet part, comprising the steps of:
casting silicon carbide powder into a preform;
machining said preform;
sintering said machined preform;
flowing molten silicon into said sintered machined preform to form a cermet structure; and
depositing a protective coating over said cermet structure.

10. The method of claim 9, wherein said depositing step includes chemical vapor deposition.

11. The method of claim 10, wherein said protective coating comprises silicon carbide.

12. The method of claim 10, wherein said protective coating comprises a carbon-based material.

13. The method of claim 12, wherein said carbon-based material comprises diamond.

14. The method of claim 12, wherein said carbon-based material comprises amorphous carbon.

15. The method of claim 9, wherein said depositing step includes thermal spraying.

16. The method of claim 15, wherein said protective layer comprises boron carbide.

17. The method of claim 9, wherein said sintering results in a shrinkage of less than 1%.

18. The method of claim 17, wherein said shrinkage is no more than 0.5%.

19. The method of claim 17, wherein said sintering is free sintering.

20. The method of claim 9, wherein said sintering is free sintering.

21. The method of claim 9, wherein said machining step includes machining two apertures through said preform arranged around respective perpendicular axes.

22. The method of claim 9, further comprising precoating pores of said sintered machine preform with carbon prior to said flowing step.

23. A vacuum chamber wall, comprising:
a base of a silicon/silicon-carbide cermet; and
a protective coating deposited on an interior of said vacuum chamber wall.

24. The vacuum chamber wall of claim 23, wherein said protective coating comprises silicon carbide.

25. The vacuum chamber wall of claim 23, wherein said protective coating comprises boron carbide.

26. The vacuum chamber wall of claim 23, wherein said protective coating comprises a carbon-based material.
